(19) United States
(12) Patent Application Publication
(10) Pub. No.: US 2009/0200895 A1
(43) Pub. Date: Aug. 13, 2009

(54) PIEZOELECTRIC ACTUATOR, COMPRISING ELECTRICALLY CONTACTED PIEZOELECTRIC ELEMENTS STACKED ON TOP OF EACH OTHER

(76) Inventors: Holger Rapp, Ditzingen (DE); Friedrich Boecking, Stuttgart (DE); Thomas Pauer, Freiberg (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 12/306,342

(22) PCT Filed: Sep. 28, 2007
(86) PCT No.: PCT/EP07/60339

§ 371 Date: Dec. 23, 2008

(30) Foreign Application Priority Data
Oct. 2, 2006 (DE) 10 2006 046 830.9
Jan. 31, 2007 (DE) 10 2007 004 874.4

(51) Int. Cl. H01L 41/047; H01L 41/083; H02N 2/04

(52) U.S. Cl. 310/314; 310/366

(57) ABSTRACT

A piezoelectric actuator is proposed, having a plurality of piezoelectric elements that are stacked on top of each other. Piezoelectric layers between each of which an inner electrode having a polarity alternating within the layer structure is provided. Outer electrodes are present at two opposing lateral surfaces, through which the inner electrodes are supplied with an electric charge. From each outer electrode at least one conductive fuse bar is directed to these inner electrodes, preferably in the inactive region, for contacting each of these inner electrodes that are associated with the polarity. The fuse bar forms an electric resistance cross-section to the respective inner electrode with the respective contact surface. In case of high current flow, the respective fuse bar blows, thus forming a fusible cut-out.

### PRIOR ART

The invention relates to a piezoelectric actuator, comprising piezoelectric elements, stacked on top of each other, that have inner electrodes that are electrically contacted, as generically defined by the characteristics of the preambles to the main claims.

A piezoelectric actuator of this kind call be used for instance in a piezoelectric injector for precise chronological and quantitative metering of fuel in an internal combustion engine. This piezoelectric injector essentially comprises a retaining body and the piezoelectric actuator, with the piezoelectric element, that is located in the retaining body.

It is known per se that to construct the aforementioned piezoelectric actuator, the piezoelectric elements can be inserted in such a way that by using what is known as the piezoelectric effect, the needle stroke of a valve or the like can be controlled. Piezoelectric layers of the piezoelectric elements are constructed from a material with a suitable crystalline structure, such that upon application of an external electrical voltage, a mechanical reaction of the piezoelectric elements ensues, which depending on the crystalline structure and the regions where the electrical voltage is applied represents a compression or tension in a predeterminable direction. Such piezoelectric actuators are suitable for instance for applications in which reciprocating motions take place under strong actuation forces and at high cycle frequencies.

For instance, one such piezoelectric actuator is known as a component of a piezoelectric injector in so-called common rail injection systems (CR injector), from German Patent Disclosure DE 10026005 A1. In this piezoelectric actuator as well. a stack of a plurality of electrically and mechanically coupled-together piezoelectric elements is constructed in such a way that it is held between two stops with initial tension via an actuator foot and an actuator head. Each piezoelectric layer of the piezoelectric elements is enclosed between two inner electrodes, by way of which an electrical voltage can be applied from outside. Because of this electrical voltage, the piezoelectric elements then each execute slight reciprocating motions in the direction of the potential drop, and these motions add up to the total stroke of the piezoelectric actuator. This total stroke is variable by way of the magnitude of the voltage applied and can be transmitted to a mechanical final control element.

In the piezoelectric actuator mentioned above, to bring about the different potentials, an alternating lateral contacting of the inner electrodes via outer electrodes is done, in which conductive faces, for instance, are applied each side face of the piezoelectric actuator and are contacted with the respective inner electrodes. In regular operation, upon charging a charging current flows to the piezoelectric actuator, while in discharging, a discharging current oriented oppositely to the charging current flows. These currents are each distributed to equal portions to the pairs of inner electrodes of the piezoelectric elements of the piezoelectric actuator, of which there are normally several hundred, in the aforementioned application as a piezoelectric injector, so that at the transition between the outer voltage lead (the outer electrode) and a respective inner electrode, normally less than 1% of the charging or discharging current flows.

From ageing processes or damage to the piezoelectric actuator, disruptive breakdowns also occur between one inner electrode as an anode and another inner electrode as a cathode. This may cause the insulation capacity of the ceramic layer of the piezoelectric layer between these inner electrodes to drop permanently, or it may lead to the development of a permanently conductive connection between these inner electrodes. In both cases, the piezoelectric actuator loses its capability to function, and in an application as a piezoelectric injector for an internal combustion engine in a vehicle, the result can be absent injection and thus the virtual failure of the affected cylinder of the engine.

In this failure situation, the entire charging current flows via the short-circuited inner electrodes and via the connection point between the outer electrode and the affected inner electrode; thus it is no longer less than 1% of the charging current that flows, but rather the entire charging current.

### DISCLOSURE OF THE INVENTION

The invention is based on a piezoelectric actuator as described at the outset, which includes a plurality of piezoelectric elements, stacked on top of each other, that have piezoelectric layers, between each of which is an inner electrode, with the polarity alternating within the layer construction. Also, on two opposed side faces of the piezoelectric actuator, there are outer electrodes by way of which the inner electrodes are supplied with an electrical charge. According to the invention, advantageously, from the respective outer electrode for contacting the inner electrodes associated with that polarity, conductive cut-out bars are extended to these inner electrodes.

The various resistor cross sections of the cut-out bars therefore burn through in the event of a high current flow and thus form a fusible cut-out in a simple way. It is thus assured in a simple way that the inner electrodes affected in the event of a disruptive breakdown will shut off automatically, and the piezoelectric actuator will thus heal itself.

It is especially advantageous if the cut-out bars are disposed in an inactive region, preferably in the side region, of the piezoelectric actuator, in which upon contacting of the outer electrodes with a respective inner electrode, the respective other inner electrode of opposite polarity is recessed by a predetermined amount. In the active region of the piezoelectric actuator cross section, in which the inner electrodes (anode) and the inner electrodes (cathode) overlap, a virtually homogeneous axially oriented electrical field develops in the piezoelectric ceramic of the piezoelectric layers, and under its influence, the piezoelectric ceramic expands for the requisite stroke. The aforementioned inactive regions of the piezoelectric actuator, in each of which only inner electrodes of one polarity occur, are also known as ISO zones.

The embodiment according to the invention with the mounting of cut-out bars in the so-called ISO zone is advantageous above all because as a result, the conductive faces are sharply reduced in their width where the current flow takes place from the outer electrode to the active region of the inner electrodes. In the first exemplary embodiment, this can either already be effected at or near the contact point of the inner electrode with the respective outer electrode, or in the other embodiment, it can be shifted farther into the inner region of the piezoelectric actuator, so as not to weaken the outer contact points electrically and/or mechanically. The contact points between the inner electrode and the outer electrode can then remain unchanged, and the constriction or the cut-out bars on the inner electrode can then be mounted with only a slight spacing from the outer electrode.

In normal operation, the mounting of the cut-out bars in accordance with the invention does not affect the function of the piezoelectric actuator, as long as the change in the inner electrode geometry takes place only in the ISO zone, and the normal current load of less than 1% of the charge current via an inner electrode does not cause an overload, even at the constriction of the cut-out bar. In the event of an error, if because of the low resistance an overly high or practically the same charging current flows via a pair of inner electrodes, then conversely the constriction acts as a fuse and is destroyed. As a result, the inner electrodes affected by the short circuit or the sparkover are decoupled from the outer electrodes and are no longer supplied with an electrical charge. As consequence, an electrical field no longer develops at these inner electrodes, and consequently there can no longer be any flow of current across the disruptive breakdown point. After the event of a disruptive breakdown the piezoelectric actuator functions completely normally again within the briefest possible time; only the number of active piezoelectric elements will have decreased by several hundred, and the actuator stroke consequently drops to the negligible range of parts per thousand In a fuel injection system with a piezoelectric injector, however, this is not even perceptible to the vehicle driver, and hence the error, which otherwise would cause failure of a cylinder, remains without consequences to the vehicle.

It is also advantageous here if the at least one cut-out bar is mounted between a partial face of the inner electrode that is contacted with the respective outer electrode, and the face, essentially located in the interior of the piezoelectric actuator, of the respective inner electrode. Because the cut-out bar is disposed with spacing from the outer electrode, an unwanted decontacting from mechanical factors can be averted in a simple way.

In the event that the conductive cut-out bars are disposed in the region of the contacting between the outer electrodes and inner electrodes, the conductive cut-out bars can preferably be applied jointly to the side faces of the piezoelectric actuator during a printing process for the geometry of the outer electrodes, and the outer electrodes can be fired or can comprise a conductive adhesive system.

In the event that the conductive cut-out bars are disposed between a partial face, contacted with an outer electrode, of the respective inner electrode and the face, located essentially in the interior of the inner electrode, of the respective inner electrode, the conductive cut-out bars can preferably be generated during a printing process for the geometry of the inner electrodes.

In the axial layer construction of the piezoelectric actuator, the cut-out bars can each be disposed one above the other at identical positions or largely at respective different positions on top of each other. The latter is especially advantageous, since then the regions of the actuator that are additionally passivated by the recess in the inner electrode do not come to rest in one line one above the other, and thus the internal mechanical stresses that occur upon an actuation of the piezoelectric actuator are sharply reduced. It can be assumed that in the regions additionally passivated by the recess, additional polarization cracks will not occur when these recessed regions are located at different positions in the various layers.

For attaining the advantages of the invention, it is not necessary that all the inner electrodes be embodied with cut-out bars; for example, it may suffice for an inner electrode that is especially threatened with short circuiting, if that inner electrode is known, to be provided with a cut-out bar.

### BRIEF DESCRIPTION OF THE DRAWINGS

Exemplary embodiment of the piezoelectric actuator of the invention will be described in detail in conjunction with the drawings.

FIG. 1 is a section through a piezoelectric actuator with a multilayer construction of piezoelectric layers, inner electrodes and outer electrodes, in accordance with the prior art; and

FIG. 2 is a detail in longitudinal section of a side face of a piezoelectric actuator, with cut-out bars mounted in accordance with the invention;

FIG. 3 is a detail in cross section of a side face of a piezoelectric actuator. with cut-out bars mounted in accordance with the invention;

FIG. 4 is a top view of contacted inner electrodes of a piezoelectric element in the prior art;

FIG. 5 is a top view of contacted inner electrodes of a piezoelectric element, with a cut-out bar according to the invention between the outer electrode and the inner electrode; and

FIG. 6 is a top view of contacted inner electrodes of a piezoelectric element, with a cut-out bar according to the invention between the outer electrode, contacted via a partial face of the inner electrode, and the inner electrode faces in the interior of the piezoelectric actuator.

### EMBODIMENTS OF THE INVENTION

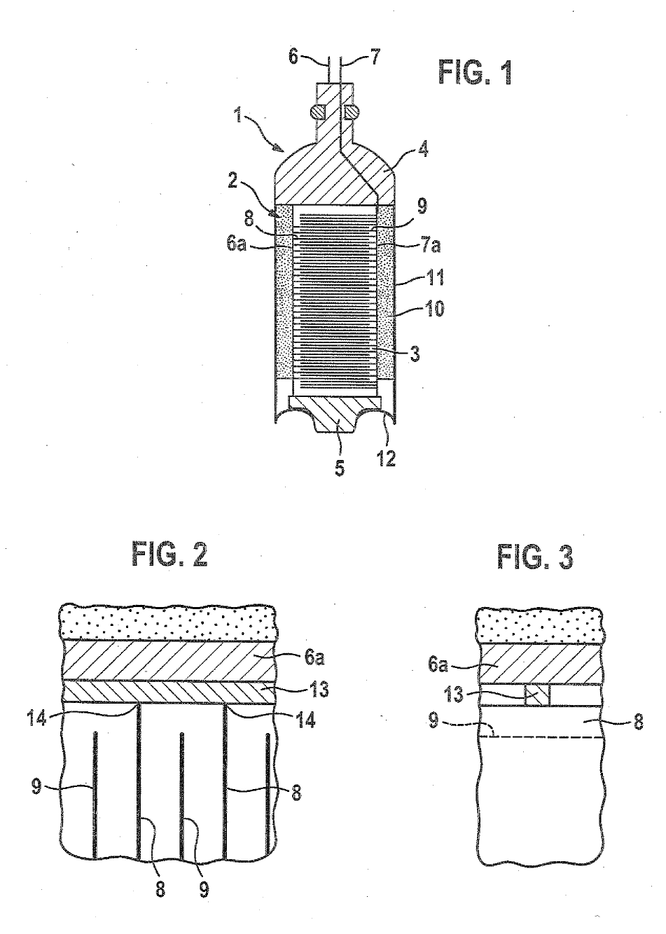

In FIG. 1, to explain the technical background of the invention, a conventional arrangement 1 known per se, with a piezoelectric actuator 2, is shown, which can be used for instance for controlling the needle stroke in the injection system for fuel in an internal combustion engine. Piezoelectric elements 3 are a component of the piezoelectric actuator 2, and the piezoelectric actuator is fastened between an actuator foot 4 and an actuator head 5, for instance of steel. Electrical leads 6 and 7 extend through the actuator foot 4 and are contacted via outer electrodes 6a and 7a with inner electrodes 8 and 9 at the piezoelectric elements 3. Upon an actuation of the piezoelectric actuator 2 by subjection of the inner electrodes 8 and 9 to voltage, a mechanical arrangement, here located vertically below the actuator head 5, can be actuated in such a way that uncovering of a nozzle opening, for instance, occurs.

The arrangement 1 having the piezoelectric actuator 2 is built into an injector body, not shown here, and the fuel flows past the arrangement 1 through the interior of the injector body. This fuel can then be effected, at the rail pressure mentioned in the background section or at a different predeterminable pressure, into the combustion chamber of an internal combustion engine injection system, not shown here. The piezoelectric elements 3 and the inner electrodes 8 and 9 have been provided with a reference numeral here only as an example. The piezoelectric actuator 2 of FIG. 1 furthermore has an insulation layer 10, which in turn is closed with a sleeve 11 and a diaphragm 12.

In FIG. 2, a detail can be seen of the piezoelectric actuator 2 in longitudinal section, in the region of the contacting of the inner electrodes 8 and 9. For example, once again, the outer electrode 6a for contacting the inner electrodes 8 is shown in detail (the outer electrode 7a for contacting the inner electrodes 9 with the respective other polarity is embodied identically) and is provided according to the invention with cut-out bars 13, which each form one resistor cross section that, together with the respective contact face 14 with the respectively contacted inner electrode 8 on the inner end of the cut-out bar 13, acts as a fusible cut-out.

FIG. 3 shows the arrangement, described above in conjunction with FIG. 2, in cross section, so that here the cut-out bar 13 as a resistor cross section is clearly seen and is dimensioned such that it burns through in the event of a high current flow and thus in a simple way forms a fusible cut-out.

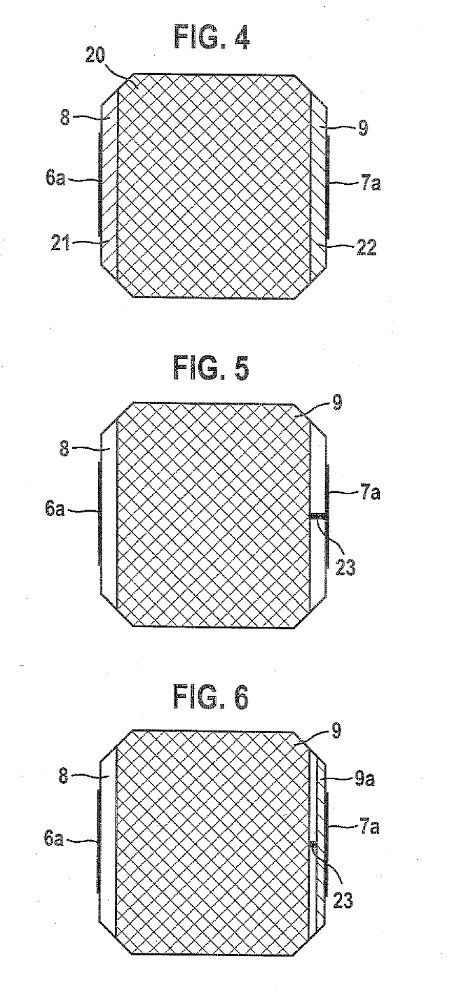

From FIG. 4, the conventional construction of the inner electrodes of a piezoelectric element 3 without cut-out bars can be seen in a top view; each of the inner electrodes 8 and 9 is shaded differently. A middle overlapping region of the inner electrodes 8 and 9, in the form of an active region 20, and a lateral inactive region 21 and 22 as an ISO zone, are visible here; the inactive region is occupied only by inner electrodes 8 or 9, each of a respective polarity. The contour of the piezoelectric actuator 2 and thus of the inner electrodes 8 and 9 and piezoelectric elements 3 can be arbitrary, for instance including a round cross section.

FIG. 5 shows an exemplary embodiment of the invention with one cut-out bar 23 between the outer electrode 7a and the central face of the inner electrode 9. The one cut-out bar 23 is disposed centrally here, but a plurality of cut-out bars 23 disposed in other ways may also be provided.

In FIG. 6, it is shown for example that the at least one cut-out bar 23 is also mounted between a partial face 9a of the respective inner electrode 9, which partial face is contacted with the outer electrode 7a, and the face, located substantially in the interior of the piezoelectric actuator, of the respective inner electrode 9, as a result of which unwanted decontacting from mechanical factors can be prevented here.

1-12. (canceled)

13. A piezoelectric actuator, comprising:
a plurality of piezoelectric elements stacked on top of each other, that have piezoelectric layers;
respective inner electrodes of alternating polarity between each layer;
outer electrodes located on two diametrically opposed side faces, byway of which outer electrodes the inner electrodes are supplied with an electrical charge; and
at least one conductive cut-out bar extended to the inner electrodes from the respective outer electrode for contacting the inner electrodes each associated with that polarity and forming an electrical resistor cross section with a respective contact face with the respective inner electrode.

14. A piezoelectric actuator, comprising:
a plurality of piezoelectric elements stacked on top of each other, that have piezoelectric layers;
respective inner electrodes of alternating polarity in a layer construction;
outer electrodes located on two diametrically opposed side faces, by way of which outer electrodes the inner electrodes are supplied with an electrical charge; and
an inactive region in which, upon contacting of the outer electrodes and a respective one of the inner electrodes, a respective other inner electrode of opposite polarity is recessed by a predetermined amount, wherein inside the inactive region, from a respective outer electrode for contacting each of the inner electrodes associated with that polarity, at least one conductive cut-out bar is extended to the inner electrodes and forms an electrical resistor cross section with the respective inner electrode.

15. The piezoelectric actuator as defined by claim 13, wherein the at least one cut-out bar is mounted between a partial face of the inner electrode that is contacted with the respective outer electrode, and the face, essentially located in an interior of the piezoelectric actuator, of the respective inner electrode.

16. The piezoelectric actuator as defined by claim 14, wherein the at least one cut-out bar is mounted between a partial face of the inner electrode that is contacted with the respective outer electrode, and the face, essentially located in an interior of the piezoelectric actuator, of the respective inner electrode.

17. The piezoelectric actuator as defined by claim 13, wherein the resistor cross section of the respective cut-out bar and/or the contact face is dimensioned such that in the event of a high current flow from the outer electrodes to the inner electrodes, the respective cut-out bar bus through and thus forms a fusible cut-out.

18. The piezoelectric actuator as defined by claim 14, wherein the resistor cross section of the respective cut-out bar and/or the contact face is dimensioned such that in the event of a high current flow from the outer electrodes to the inner electrodes, the respective cut-out bar burns through and thus forms a fusible cut-out.

19. The piezoelectric actuator as defined by claim 13, wherein the cut-out bars are applied to the side faces of the piezoelectric actuator during a printing process for the geometry of the outer electrodes.

20. The piezoelectric actuator as defined by claim 14, wherein the cut-out bars are applied to the side faces of the piezoelectric actuator during a printing process for the geometry of the outer electrodes.

21. The piezoelectric actuator as defined by claim 13, wherein the cut-out bars are generated by the shaping of the inner electrodes during a printing process for the geometry of the inner electrodes.

22. The piezoelectric actuator as defined by claim 14, wherein the cut-out bars are generated by the shaping of the inner electrodes during a printing process for the geometry of tie inner electrodes.

23. The piezoelectric actuator as defined by claim 13, wherein in the layer construction of the piezoelectric actuator, the cut-out bars are each disposed at identical positions, one above the other.

24. The piezoelectric actuator as defined by claim 14, wherein in the layer construction of the piezoelectric actuator, the cut-out bars are each disposed at identical positions, one above the other.

25. The piezoelectric actuator as defined by claim 13, wherein in the layer construction of the piezoelectric actuator, the cut-out bars are each disposed at different positions, on top of each other.

26. The piezoelectric actuator as defined by claim 14, wherein in the layer construction of the piezoelectric actuator, the cut-out bars are each disposed at different positions, on top of each other.

27. The piezoelectric actuator as defined by claim 13, wherein in the layer construction of the piezoelectric actuator, the at least one cut-out bar is disposed on at least one especially short-circuit-threatened inner electrode.

28. The piezoelectric actuator as defined by claim 14, wherein in the layer construction of the piezoelectric actuator, the at least one cut-out bar is disposed on at least one especially short-circuit-threatened inner electrode.

29. The piezoelectric actuator as defined by claim 13, wherein the outer electrodes are fired.

30. The piezoelectric actuator as defined by claim 14, wherein the outer electrodes are fired.

31. The piezoelectric actuator as defined by claim 13 wherein the outer electrodes comprise a conductive adhesive system.

32. A piezoelectric injector, including a retaining body and a piezoelectric actuator, disposed in the retaining body between an actuator head and an actuator foot, the piezoelectric actuator comprising
a plurality of piezoelectric elements stacked on top of each other, that have
piezoelectric layers,
respective inner electrodes of alternating polarity between each layer,
outer electrodes located on two diametrically opposed side faces, by way of which outer electrodes the inner electrodes are supplied with an electrical charge, and
at least one conductive cut-out bar extended to the inner electrodes from the respective outer electrode for contacting the inner electrodes each associated with that polarity and forcing an electrical resistor cross section with a respective contact face with the respective inner electrode.
